(19) United States
(12) Patent Application Publication
(10) Pub. No.: US 2025/0306478 A1
(43) Pub. Date: Oct. 2, 2025

(54) METHOD AND SYSTEM FOR PHOTOMASK DELIVERY

(71) Applicant: TAIWAN SEMICONDUCTOR MANUFACTURING COMPANY LTD., HSINCHU (TW)

(72) Inventors: KAI-WEN HSIAO, KAOHSIUNG CITY (TW); FU-YU HSU, HSINCHU CITY (TW)

(21) Appl. No.: 18/617,668

(22) Filed: Mar. 27, 2024

(51) Int. Cl. G03F 7/00; G03F 1/66; G03F 1/82; G06T 7/00; G06T 7/70

(52) U.S. Cl. CPC G03F 7/70741; G03F 1/66; G03F 1/82; G03F 7/70033; G06T 7/0004; G06T 7/70; G06T 2207/10048; G06T 2207/30148

(57) ABSTRACT

A system for delivering a photomask is provided. The system includes a first tool and a second tool. Each of the first and the second tools is configured to handle a photomask. The system also includes a vehicle configured to move the photomask from the first tool to the second tool. A container is positioned in the vehicle and the photomask is received in the container. The system further includes an image capturing module used to produce an image of the photomask while the photomask is received within the container. In addition, the system includes a processing device used to determine whether the delivery of the photomask with the use of the vehicle from the first tool to the second tool continues based on an image analysis of the image of the photomask.

### BACKGROUND

Semiconductor fabrication relies on the process of photolithography, in which light of a given frequency is used to transfer a desired pattern onto a wafer undergoing semiconductor processing. To transfer the pattern onto the wafer, a photomask (also referred to as a mask or reticle) is often used. The photomask permits and prevents light in a desired pattern onto a layer of the wafer, such as a photoresist (PR) layer, which chemically reacts to the light exposure, removing some portions of the PR and leaving other portions. The remaining PR is then used to pattern an underlying layer.

As the semiconductor technology advances, more complex circuits/structures having smaller sizes have been integrated to a semiconductor device. In the course of semiconductor device evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. However, such scaling down has also increased the complexity of manufacturing processes in both photomask fabrication process and semiconductor fabrication process.

For example, during the fabrication of a photomask, the substrate carrying the pattern needs to be transferred between various tools. As the complexity of the photomask pattern grows, the manufacturing procedures become more extensive, leading to a higher frequency of transfers. Mishandling during these transfers can lead to scraping of the photomask substrates, thereby increasing manufacturing expenses. Moreover, it can adversely affect the production process of other photomask substrates and prolong the fabrication time.

### BRIEF DESCRIPTION OF THE DRAWINGS

Aspects of the embodiments of the present disclosure are best understood from the following detailed description when read with the accompanying figures. It is noted that, in accordance with the standard practice in the industry, various structures are not drawn to scale. In fact, the dimensions of the various structures may be arbitrarily increased or reduced for clarity of discussion.

FIG. 1 shows a simplified block diagram of an integrated circuit (IC) manufacturing system, along with an IC manufacturing flow associated with the IC manufacturing system, in accordance with one or more embodiments of the present disclosure.

FIG. 2 shows one exemplary embodiment of a mask house, in accordance with some embodiments of present disclosure.

FIG. 3 shows one exemplary embodiment of a vehicle for delivering a photomask, in accordance with some embodiments of present disclosure.

FIG. 4 shows a schematic view of a supporting rack and a container with a photomask received therein, in accordance with some embodiments of present disclosure.

FIG. 5 shows a simplified block diagram of a system for delivering a photomask, in accordance with some embodiments of present disclosure.

FIG. 6 shows an image of a photomask took during a transportation of the photomask, in accordance with some embodiments of present disclosure.

FIG. 7 shows a bottom schematic view of container with a photomask received therein, in accordance with some embodiments of present disclosure.

FIG. 8 shows a flow chart illustrating a method for delivering a photomask, in accordance with some embodiments of present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation.

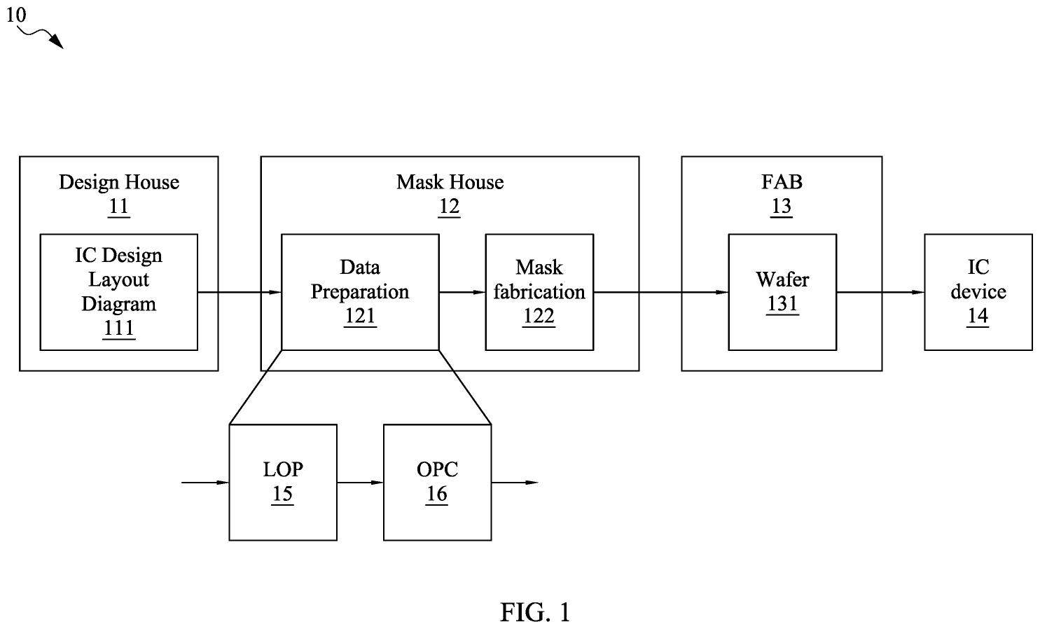

FIG. 1 is a simplified block diagram illustrating an embodiment of an integrated circuit (IC) manufacturing system 10 and an IC manufacturing flow associated with the IC manufacturing system 10. The IC manufacturing system 10 comprises a plurality of entities, such as a design house 11, a mask house 12, and an IC manufacturer 13, that interact with one another in the design, development, and manufacturing cycles and/or services related to manufacturing an IC device 14. The plurality of entities may be connected by a communications network, which may be a single network or a variety of different networks, such as an intranet and the Internet, and may include wired and/or wireless communication channels. Each entity may interact with other entities and may provide services to and/or receive services from the other entities. The design house 11, mask house 12, and IC manufacturer 13 may be a single entity or separate entities.

For example, when an IC is to be manufactured, a tape-out process is performed. The tape-out process may include a floor planning process in which the various structures making up the IC are provided in a design layout. The process may include generating an electronic file of the design layout in a graphic data stream (GDS) format. The design layout GDS file is checked by a design rule check (DRC) tool to ensure the design layout complies with various design rules such as a minimum density rule. It is understood that other types of file formats may be also be used in this example. The process continues with an assembly process. The circuit design may be partitioned into various blocks, each block performing a specific function. Accordingly, the various blocks are assembled together and the entire design layout is ready for photomask (or mask) processing.

During the design stage, the design house 11 generates an IC design layout 111. The IC design layout 111 includes various geometrical patterns designed for an IC product, based on a specification of the IC product to be manufactured. The geometrical patterns correspond to patterns of metal, oxide, or semiconductor layers that make up the various components of the IC device 14 to be fabricated. The various layers combine to form various IC features. For example, a portion of the IC design layout 111 may include various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. The design house 11 implements a proper design procedure to form the IC design layout 111. The design procedure may include logic design, physical design, and/or place and route. The IC design layout 111 is presented in one or more data files having information of the geometrical patterns. For example, the IC design layout 111 can be expressed in a GDSII file format.

During the photomask fabrication stage, The mask house 12 uses the IC design layout 111 to manufacture one or more masks (or photomask) to be used for fabricating the various layers of the IC product according to the IC design layout 111. The mask house 12 performs mask data preparation 121, where the IC design layout 111 is translated into a form that can be physically written by a mask writer, and mask fabrication 122, where a mask is fabricated according to the mask pattern generated by mask data preparation 121. A number of mask images may be generated based on the finished design layout. The number of mask images will vary depending on the complexity of the design layout. The process is now in a tape-out stage which represents when the design layout (or database) is ready for the chip manufacture.

The mask data preparation 121 may also include a logic operation (LOP) 15 and an optical proximity correction (OPC) 16.

The LOP 15 is performed on the IC design layout 111 to modify the IC design layout 111 according to manufacturing rules. For example, the conversion process may be implemented by software in LOP 15. Various manufacturer modules convert manufacturing constraints into a set of rules that the IC design layout 111 has to meet. If the IC design layout 111 does not meet this set of rules, the IC design layout 111 will be modified accordingly until the modified IC design layout meets these rules. Such modification is implemented by the LOP 15.

The OPC 16 is resolution enhancement techniques. The OPC 16 (or model-based OPC) is a lithography enhancement technique used to compensate for image errors, such as those that can arise from diffraction, interference, or other process effects. The OPC 16 features, such as scattering bars, serif, and/or hammerheads, are added to the IC design layout 111 according to optical models or rules such that, after a lithography process. The mask data preparation 121 can include further resolution enhancement techniques, such as off-axis illumination, sub-resolution assist features, phase-shifting masks, other suitable techniques, or combinations thereof.

The OPC 16 accounts for distortion in the pattern transfer process with modification of the design shapes in order to print the desired images on the wafer. The OPC 16 may include general modifications for the limitation in the lithography process, and in one particular example accounts for the case of optical lithography. The OPC 16 may include modifications of the design image account for optical limitations as well as mask fabrication limitations and resist limitations. Modifications of the design image can also account for the subsequent process steps like dry etching or implantation. It can also account for flare in the optical system as well as pattern density variations. Another application of proximity effect correction is the compensation of the effects of aberrations of the optical system used to print the image of the mask onto the wafers.

The mask data preparation 121 may further include other processes, including but not limited to various pre-OPC and post-OPC processes. In one example, post-OPC processes include but are not limited to a lithographic process check (LPC) that simulates processing that will be implemented by the IC manufacturer 13 to fabricate the IC device 14, and various quality assurance processes (e.g., difference region alignment quality assurance and LPC check of boundary regions, XOR, CRC). LPC may simulate this processing based on the modified IC design layout to create a simulated manufactured device, such as the IC device 14. The simulated manufactured device may be all or a portion of the IC design layout. In the present embodiment, the LPC may simulate processing of the modified IC design layout, which has been subjected to the LOP 15 and OPC 16.

LPC may determine whether the simulated manufactured device violates any of the plurality of hot spot rules. If the simulated manufactured device satisfies the hot spot rules, the mask data preparation may be completed. Alternatively, the modified IC design layout is subjected to further model-based testing, rule-based testing, and/or otherwise modified or tested to further improve the design and/or layout of the device before the manufacturing phase.

After the mask data preparation 121, a mask or group of masks are fabricated based on the modified IC design layout. For example, an electron-beam (e-beam) or a mechanism of multiple e-beams is used to form a pattern on a mask (photomask or reticle) based on the modified IC design layout. The mask can be formed in various technologies. In one embodiment, the mask is formed using binary technology. In the present embodiment, a mask pattern includes opaque regions and transparent regions. A radiation beam, such as an ultraviolet (UV) beam, used to expose the image sensitive material layer (e.g., photoresist) coated on a wafer, is blocked by the opaque region and transmits through the transparent regions. In one example, a binary mask includes a transparent substrate (e.g., fused quartz) and an opaque material (e.g., chromium) coated in the opaque regions of the mask. In another example, the mask is formed using a phase shift technology. In the phase shift mask (PSM), various features in the pattern formed on the mask are configured to have proper phase difference to enhance the resolution and imaging quality. In various examples, the phase shift mask can be attenuated PSM or alternating PSM as known in the art.

During the wafer fabrication stage, the IC manufacture 13 (i.e., the semiconductor fabrication plant (FAB)) uses the masks fabricated by the mask house 12 to fabricate the IC device 14. The IC manufacturer may be an IC fabrication business that can include a myriad of manufacturing facilities for the fabrication of a variety of different IC products. For example, there may be a manufacturing facility for the front end fabrication of a plurality of IC products (i.e., front-end-of-line (FEOL) fabrication), while a second manufacturing facility may provide the back end fabrication for the interconnection and packaging of the IC products (i.e., back-end-of-line (BEOL) fabrication), and a third manufacturing facility may provide other services for the foundry business. In the present embodiment, a wafer 131 is fabricated using the mask (or masks) to form the IC device 14.

The wafer 131 may include a silicon substrate or other proper substrate having material layers formed thereon. Other proper substrate materials include another suitable elementary semiconductor, such as diamond or germanium; a suitable compound semiconductor, such as silicon carbide, indium arsenide, or indium phosphide; or a suitable alloy semiconductor, such as silicon germanium carbide, gallium arsenic phosphide, or gallium indium phosphide. The wafer 131 may further include various doped regions, dielectric features, and multilevel interconnects (formed at subsequent manufacturing steps). The mask may be used in a variety of processes. For example, the mask may be used in an ion implantation process to form various doped regions in the wafer, in an etching process to form various etching regions in the wafer, in a deposition process (e.g., chemical vapor deposition (CVD) or physical vapor deposition (PVD)) to form a thin film in various regions on the wafer, and/or other suitable processes.

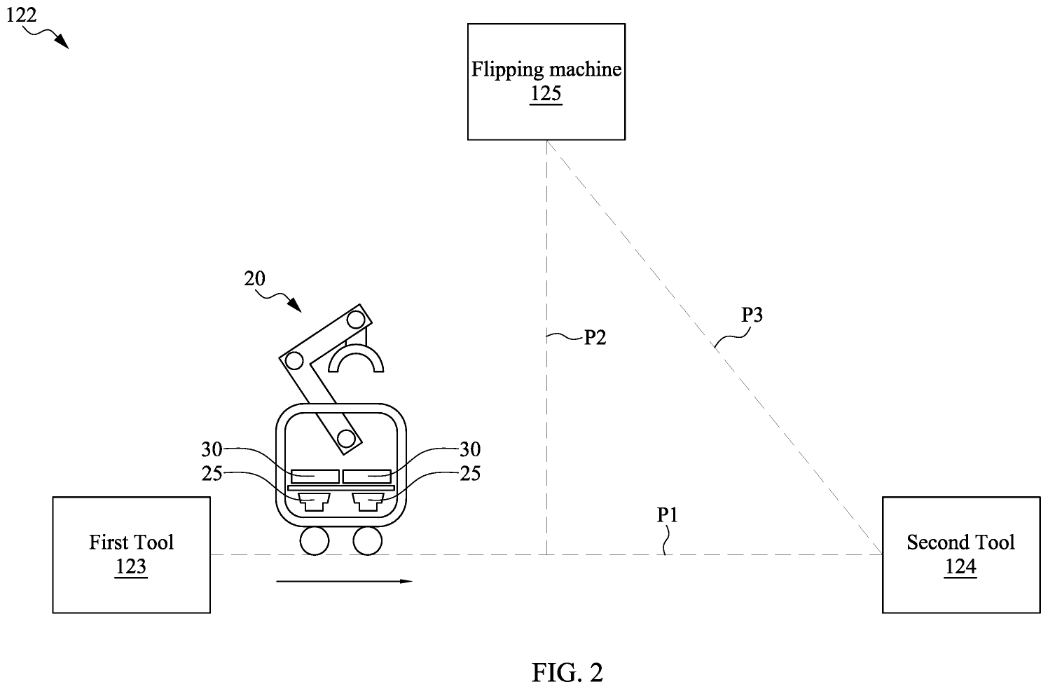

FIG. 2 shows one exemplary embodiment of the mask house 12, in accordance with some embodiments of present disclosure. The mask house 12 may use multiple tools, such as first tool 123 and second tool 124, to fabricate a photomask. In some embodiment, the first tool 123 and the second tool 124 are used to performed different mask fabrication process over the photomask. For example, each of the first tool 123 and the second tool 124 in the mask house 12 may be used to perform one of stages of a lithography process. These stages includes a spin coating process, a charged particle beam exposure process, a developing process, an etching process, a resist stripping process, and a cleaning process. In the spin coating process, an energy-sensitive resist layer is formed on the mask material layer. The mask material layer is an absorption layer, a phase shifting material layer, an opaque material layer, a portion of a mask substrate, and/or other suitable mask material layer. In charged particle beam exposure process, a pattern is directly “wrote” into the energy-sensitive resist layer using a charged particle beam, such as an electron beam or an ion beam, such as an electron beam or an ion beam. Since the energy-sensitive resist layer is sensitive to charged particle beams, exposed portions of the energy-sensitive resist layer chemically change. In the developing process, exposed (or non-exposed) portions of the energy-sensitive resist layer are dissolved during the developing process depending on characteristics of the energy-sensitive resist layer and characteristics of a developing solution used in the developing process.

After development, the patterned resist layer includes a resist pattern that corresponds with the mask pattern. The resist pattern is then transferred to the mask material layer by any suitable process, such that a final mask pattern is formed in the mask material layer. For example, the mask fabrication process may further include performing an etching process that removes portions of the mask material layer, where the etching process uses the patterned energy-sensitive resist layer as an etch mask during the etching process. After the etching process, the lithography process can include removing the patterned energy-sensitive resist layer from the mask material layer, for example, by a resist stripping process. Multiple cleaning processes may be performed during different stage. After the development process, the photomask may undergo a cleaning procedure to eliminate any residues or contaminants that could have built up during fabrication. This cleaning process may improve the accuracy and quality of the photomask.

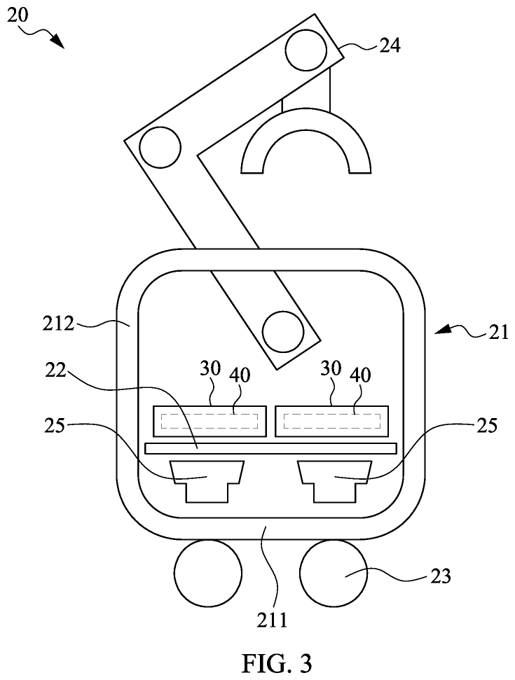

In certain embodiments, a vehicle 20 is utilized to transport one or more photomasks between the first tool 123 and the second tool 124 within the mask house 12. As depicted in FIG. 3, the vehicle 20 includes a main body 21, a supporting rack 22, wheels 23, a robot arm 24, and one or more image capturing modules 25. The main body 21 includes a bottom wall 211, and a side wall 212 that extends upward from the edges of the bottom wall 211, defining the interior of the main body 21. The interior of the main body 21 can accommodate one or more containers 30. In certain embodiments, the upper side of the main body 21 features an opening through which the robot arm 24 extends from the interior to the exterior of the main body 21. The robot arm 24 is responsible for automatically transferring the container 30 into and out of the main body 21. The vehicle 20 is equipped with wheels 23 attached to the lower side of the main body 21, facilitating its movement.

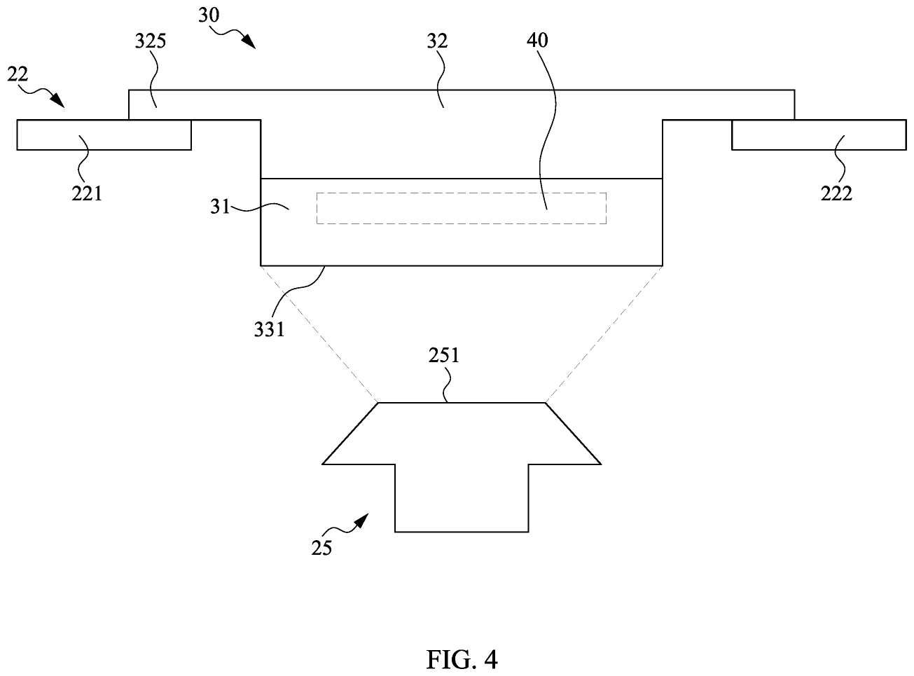

The containers 30 in the vehicle 20 may be supported by the supporting rack 22. In one exemplary embodiment, the supporting rack 22 is connected to the side wall 212 and is distant away from the bottom wall 211 of the vehicle 20. The image capturing modules 25 are positioned at the bottom wall 211 and below the supporting rack 22. In one exemplary embodiment, as shown in FIG. 4, the supporting rack 22, which is used to support the container 30, includes two rack members 221 and 222 extends parallel to each other. The container 30 includes two lids, such as lower lid 31 and upper lid 32. The upper lid 32 is detachably connected to the lower lid 31 to define an enclosed space for receiving the photomask 40. In one embodiment, the upper lid 32 includes a flange 325 extends from the upper edge of the upper lid 32 in a radical direction. The container 30 is placed on the two rack members 221 and 222 through the flange 325. The image capturing module 25 is positioned below a gap defined between the two rack members 221 and 222, and a lens 251 of the image capturing module 25 is face upward. When the container 30 is placed on the supporting rack 22, the image capturing module 25 directly faces a bottom surface 331 of the lower lid 31 of the container 30.

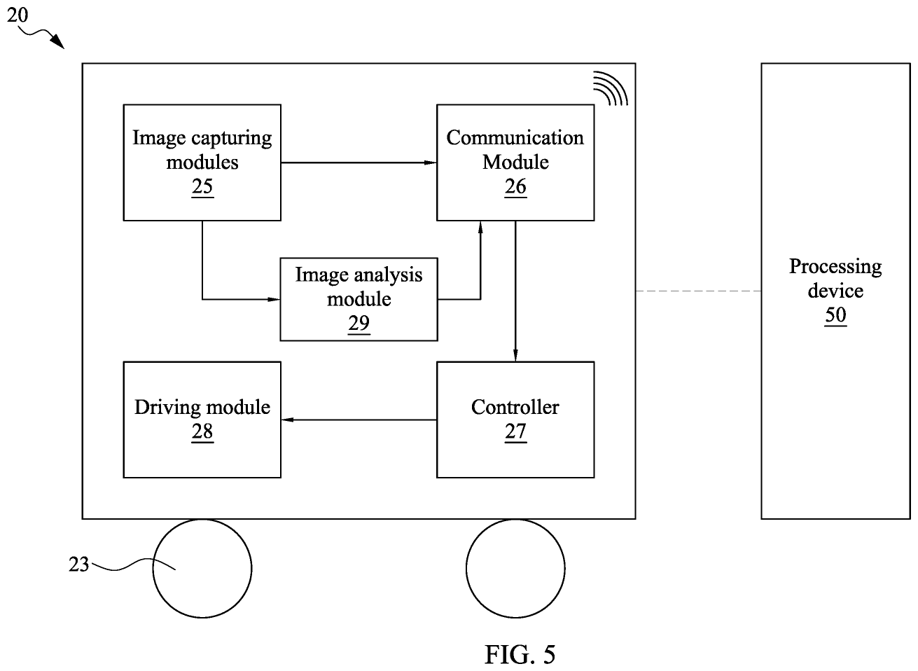

With reference to FIG. 5, in some embodiments, the vehicle 20 further comprises a number of electronic components to perform multiple operations. In some embodiments, the vehicle 20 includes various electronic components to perform multiple operations. In some embodiments, the moving path of the vehicle 20 is determined by an image of a photomask captured by the image capturing module 25. To facilitate this operation, the vehicle 20 is equipped with a communication module 26, which is connected to the image capturing module 25. The communication module 26 wirelessly transmits the data related to the photomask image to a processing device 50 for image analysis. Additionally, the communication module 26 receives a signal from the processing device 50 to control the vehicle's moving path. Upon receiving the signal, the communication module 26 transmits it to a controller 27 mounted on the vehicle 20. The controller 27 then issues a control signal to a driving module 28, such as a motor, which drives the wheels 23 to move the vehicle along the desired path.

It would be noted that various modifications and variations can be made to the disclosed embodiments. In some other embodiments, the vehicle 20 is further equipped with an image analysis module 29. The image analysis module 29 is connected to the image capturing module 25 and is used for analyzing the captured photomask image. The results of the image analysis are then transmitted to the processing device 50 through the communication module 26 to determine the vehicle's moving path. The inclusion of the image analysis module on the vehicle 20 allows for a shorter processing time for the captured image.

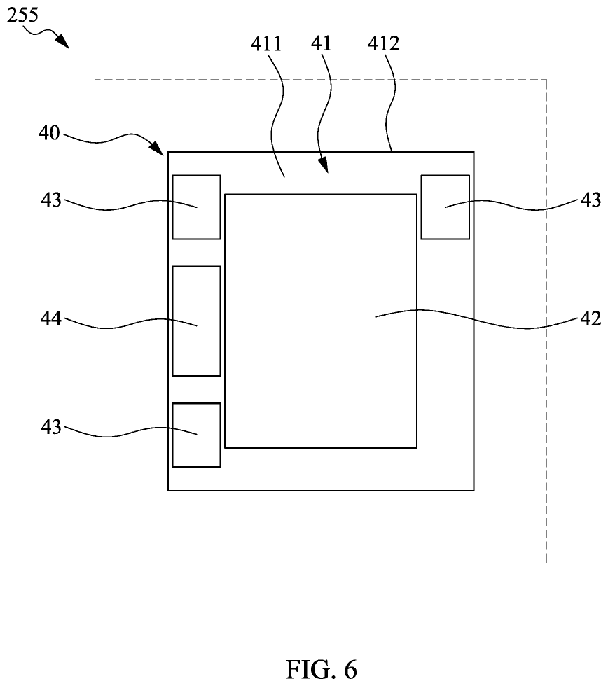

In some embodiments, the aforementioned image analysis includes analyzing the position of some elements displayed in the photomask image. FIG. 6 shows an exemplary photomask image 255 in one embodiment. In the particular embodiment, the photomask 40 may have a rectangular substrate 41. A photomask pattern 42 is printed on a front side 411 of the rectangular substrate 41 in the middle area. Multiple alignment marks 43, which can be used to assist in determining whether the photomask 40 is correctly positioned, are arranged around the photomask pattern 42 on the front side 411 of the rectangular substrate 41. In one embodiment, the number of alignment marks 43 on the sides of the photomask pattern 42 is inconsistent in order to identify the left and right positions of the photomask 40. For example, in the embodiment shown in FIG. 6, the left side of the photomask pattern 42 has two alignment marks 43, but the right side of the photomask pattern 42 has one alignment mark 43. The rectangular substrate 41 may further include a barcode 44. The photomask 40 may be printed with two-dimensional information or a QR code related to the identity of the photomask. The barcode 44 can be positioned between the two alignment marks 43.

The image analysis module 29 or processing device 50 is capable of analyzing the orientation of alignment marks 43 in the mask image to inspect the left-right and up-down directions of the mask. If the alignment marks 43 are absent in the photomask image 255, the image analysis module 29 or processing device 50 can determine that the photomask 40 is positioned upside down in the container 30. By incorporating this image analysis module 29 or processing device 50 into the mask fabrication system, the overall efficiency and accuracy of the photomask handling process can be significantly improved.

Referring back to FIG. 4, in certain embodiments, the lower lid 31 and upper lid 32 of the container 30 are constructed entirely from a partially transparent material. This material, such as polypropylene or polycarbonate, provides effective protection against dust and moisture. The term “partially transparent” as used in this disclosure refers to the pattern, such as alignment marks 43 and the barcode 44, formed on the photomask 40 is not clearly visible under visible light. Consequently, if a camera utilizing visible light for photography is employed, it will be unable to accurately capture the pattern distribution above the light shield, thus impeding the aforementioned image analysis. To address this issue, the image capturing module 25 of the present embodiments includes a short-wave infrared (SWIR) camera.

The operation principle of the SWIR camera is based on the detection and capture of light in the short-wave infrared spectrum, which ranges from approximately 900 to 2500 nanometers. The SWIR camera works by capturing the SWIR light emitted or reflected by objects. The SWIR light interacts differently with various materials compared to visible light, allowing the camera to capture the photomask image while the photomask 40 is positioned in the container 30. In the embodiment shown in FIG. 4, SWIR light can penetrate the bottom surface 331 of the lower lid 31 and be detected by a sensor array (not shown in figures) that converts the SWIR light into electrical signals. The image processing component of the SWIR camera converts these signals into a visible image or data for analysis. The sensor array in a SWIR camera is typically made of indium gallium arsenide (InGaAs) or mercury cadmium telluride (MCT) materials, which are sensitive to the SWIR wavelength range.

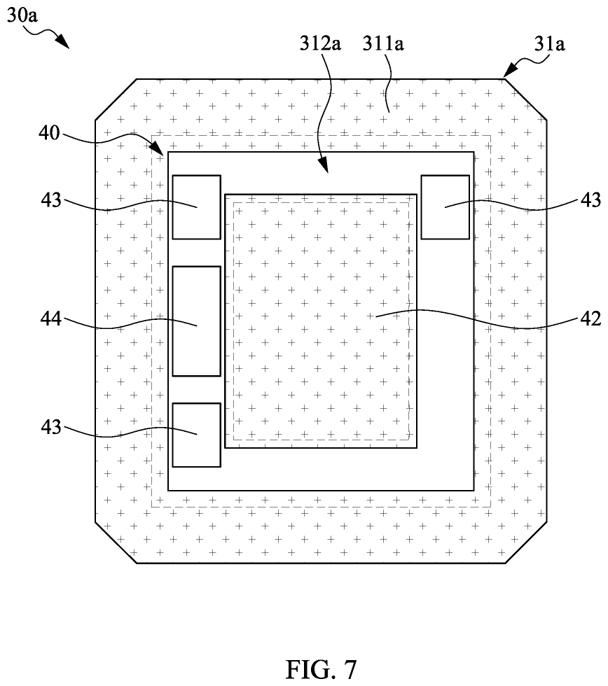

FIG. 7 shows a bottom schematic view of container 30a with the photomask 40 received therein, in accordance with some embodiments of present disclosure. The components in FIG. 7 that use the same reference numerals as the components of FIG. 4 refer to the same components or equivalent components thereof. For the sake of brevity, it will not be repeated here. In some embodiment, difference between the container 30a and the container 30 shown in FIG. 4 resides in that the lower lid 31 being replaced with a lower lid 31a. The container 30a is equipped with a lower lid 31a that features a transparent window 312a on its bottom surface 311a. This transparent window 312a allows visible light to pass through, facilitating the use of a conventional camera for inspecting the alignment marks 43 and barcode 44 on the photomask 40 when it is placed inside the container 30a. In some embodiments, the shape of the transparent window 312a corresponds to a blank region on the photomask where the alignment marks 43 and barcode 44 are located. Alternatively, the lower lid 31a may include multiple transparent windows 312a, each aligned with predetermined positions where the alignment marks 43 of the photomask 40 is located if the photomask 40 is correctly positioned in the container 30a.

Although in the embodiments shown in FIGS. 3 and 4, the image capturing module 25 is positioned directly facing the bottom surface 331 of the lower lid 31 to inspect the alignment marks 43 and barcode 44 on the photomask 40 through the bottom surface 331 of the lower lid 31, the present invention is not limited to this. In some other embodiments, depending on the preset condition of the photomask 40, the image capturing module 25 is positioned directly facing the upper lid 32 and inspects the alignment marks 43 and barcode 44 on the photomask through the upper lid 32. In some other embodiments, the image capturing module 25 is attached to the side wall 212 of the vehicle 20 and is inclined relative to the container 30, instead of being positioned directly facing the lower lid 31 or upper lid 32 of the container 30. In yet other embodiments, the image capturing module 25 is arranged so as to capture images of the two positions in the vehicle 20 used for receiving the container 30, thereby reducing the cost of setting up the image capturing module 25. In still yet some other embodiments, the image capturing module 25 is not positioned on the vehicle 20, and is positioned on a check point in the mask house 12. When the vehicle 20 is moved to the check point, an image of the photomask 40 is produced by the image capturing module 25.

Additionally, while the vehicle 20 depicted in FIG. 2 is primarily utilized for transferring the photomask during mask fabrication 122, it can also serve as a means for transferring the photomask in various other locations. For instance, the vehicle 20 can facilitate the delivery of one or more photomasks between different exposure tools within the FAB 13, or between an exposure tool and a photomask stock. Utilizing the vehicle 20 within the FAB 13 helps alleviate concerns regarding potential contamination or scratching of the photomask if it is mistakenly placed on the exposure tool with an incorrect orientation.

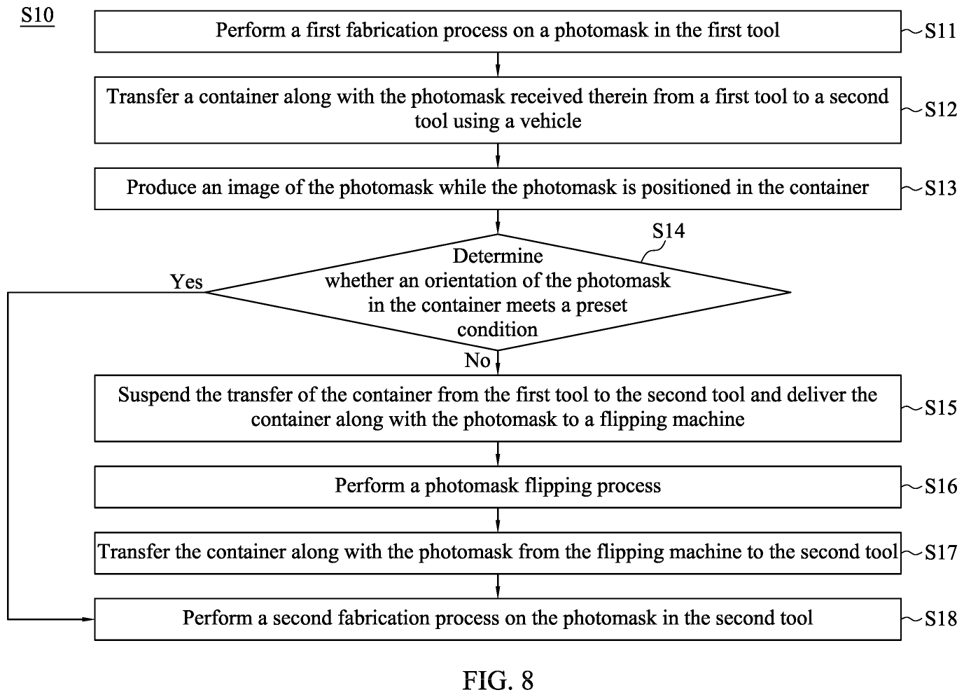

FIG. 8 shows a flow chart illustrating a method S10 for delivering a photomask, in accordance with some embodiments of present disclosure. For illustration, the flow chart will be described along with the drawings shown in FIGS. 2-4. Some of the described stages can be replaced or eliminated in different embodiments.

In operation S11, the photomask 40 undergoes a first fabrication process in the first tool 123. This process may involve spin coating, charged particle beam exposure, developing, etching, or resist stripping. In operation S12, the container 30 or 30a, along with the photomask 40, is transferred from the first tool 123 to the second tool 124 using the vehicle 20. The vehicle 20 can be activated to move along the first moving path P1. In operation S13, the image capturing module 25 captures an image of the photomask 40 while the photomask 40 is positioned inside the container 30.

In operation S14, the image captured by the image capturing module 25 is utilized for image analysis to verify if the orientation of the photomask in the container meets a preset condition. If the photomask 40 is correctly positioned within the container 30, the method S10 proceeds to operation S18. In operation S18, a second fabrication process is carried out on the photomask 40 using the second tool 124. This second fabrication process can involve a cleaning process, where either the front or back side of the photomask 40 is cleaned to eliminate any unwanted residues. Alternatively, the second fabrication process may include a charged particle beam exposure process, which transfers a pattern onto a layer formed on the photomask.

In the image analysis, the image captured in real-time by the image capturing module 25 is compared with the image 255 (FIG. 6) recorded in the image analysis module 29 or processing device 50. The image 255 represents the correctly placed photomask 40 in the container 30. If the real-time image matches the image 255 is identical to the image 255, the image analysis module 29 or processing device 50 determines that the photomask 40 is correctly positioned in the container 30. If the photomask 40 is incorrectly positioned in the container 30, the method S10 proceeds to operation S15, in which the transfer of the container from the first tool 123 to the second tool 124 is halted, and the processing device 50 may send a signal to activate the vehicle 20 to transport the container 30, along with the photomask 40, to a flipping machine 125. The image analysis may be used to perform an up-down check, a left-right check, or a flip-or-not check.

As shown in FIG. 2, the vehicle 20 may move along the second moving path P2 to the flipping machine 125. The second moving path P2 is connected to the first moving path Pl at one end, and terminates at the flipping machine 125 at the other end. When the vehicle 20 approaches the flipping machine 125, a photomask flipping process is initiated (operation S16). This process involves moving the container 30 to the flipping machine 125, where one or more robot (not shown in figures) open the container 30 and adjust the orientation of the photomask 40 to ensure it is correctly positioned in the container 30. The flipping machine 125 can change the orientation based on the image captured by the image capturing module 25. When the photomask 40 is correctly positioned in the container 30, the method S10 continues to operation S17, in which the container 30 is transferred to the second tool 124 for the second fabrication process. By ensuring the correct orientation of the photomask by using the image capturing module 25, the risk of scraping the photomask is minimized.

Embodiments of the present disclosure provide a system and method for inspecting a photomask within a container, which is carried by a vehicle, using an image capturing module. The real-time image of the photomask is analyzed to determine if it is positioned correctly in the container according to a preset condition. If any abnormalities are detected in the image analysis, the orientation of the photomask is adjusted before it is delivered to the next processing tool. Since every photomask used or fabricated by the next processing tool is in the correct orientation, the subsequent processes can operated accurately. In addition, scrapping of the photomask can be avoided or eliminated, resulting in reduced manufacturing expenses and preventing delays in delivering the product to the customer.

According to other embodiments of present disclosure, a system for delivering a photomask is provided. The system includes a first tool and a second tool. Each of the first and the second tools is configured to handle a photomask. The system also includes a vehicle configured to move the photomask from the first tool to the second tool. A container is positioned in the vehicle and the photomask is received in the container. The system further includes an image capturing module, configured to produce an image of the photomask while the photomask is received within the container. In addition, the system includes a processing device configured to determine whether the delivery of the photomask with the use of the vehicle from the first tool to the second tool continues based on an image analysis of the image of the photomask.

According to some embodiments of present disclosure, a vehicle for delivering a photomask is provided. The vehicle includes a main body and a container. The container is removably positioned in the main body and configured to receive the photomask. The vehicle also includes an image capturing module positioned in the main body. The image capturing module is also configured to produce an image of the photomask while the photomask is received within the container. The vehicle further includes an image analysis module configured to analyze the image of the photomask captured by the image capturing module so as to determine if the photomask is positioned according to a preset condition.

According to some embodiments of present disclosure, a method for delivering a photomask is provided. The method includes transferring a container along with the photomask received therein from a first tool to a second tool using a vehicle. The method also includes producing an image of the photomask while the photomask is positioned in the container. The method further includes determining whether an orientation of the photomask in the container meets a preset condition. When the orientation of the photomask does not meet the preset condition, the transfer of the container from the first tool to the second tool is suspended and the container along with the photomask is delivered to a flipping machine. In addition, the method includes performing a photomask flapping process on the photomask when the orientation of the photomask does not meet the preset condition.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes. substitutions, and alterations herein without departing from the spirit and scope of the present disclosure.

What is claimed is:

1. A system, comprising:
a first tool;
a second tool, wherein each of the first and the second tools is configured to handle a photomask;
a vehicle, configured to move the photomask from the first tool to the second tool, wherein a container is positioned in the vehicle and the photomask is received in the container;
an image capturing module, configured to produce an image of the photomask while the photomask is received within the container; and
a processing device, configured to determine whether the delivery of the photomask using the vehicle from the first tool to the second tool continues based on an image analysis of the image of the photomask.

2. The system as claimed in claim 1, wherein the image capturing module is fixed on the vehicle.

3. The system as claimed in claim 2, further comprising an image analysis module positioned on the vehicle and configured to perform the image analysis, wherein a result of the image analysis is transmitted to the processing device to determine whether the delivery of the photomask continues.

4. The system as claimed in claim 1, further comprising a flipping machine configured to change an orientation of photomask, wherein when the image analysis shows an abnormality, the processing device is configured to:
issue a first signal to suspend the delivery of the photomask from the first tool to the second tool; and
issue a second signal to drive the vehicle moving to for a photomask flapping process.

5. The system as claimed in claim 1, wherein the first and the second tools are used for fabricating of the photomask.

6. The system as claimed in claim 5, wherein the second tool is used for cleaning the photomask.

7. The system as claimed in claim 5, wherein the second tool is used for transferring a pattern to a layer formed over the photomask.

8. The system as claimed in claim 1, wherein the container is partially transparent, and the image capturing module is a short-wave infrared (SWIR) camera.

9. The system as claimed in claim 1, wherein the container comprises a lid which includes a transparent window, and the image capturing module tool takes images of the photomask via the transparent window.

10. The system as claimed in claim 1, wherein the photomask comprises an EUV mask.

11. A vehicle for delivering a photomask, comprising:
a main body;
a container removably positioned in the main body and configured to receive the photomask;
an image capturing module positioned in the main body and configured to produce an image of the photomask while the photomask is received within the container; and
an image analysis module configured to analyze the image of the photomask captured by the image capturing module so as to determine if the photomask is positioned according to a preset condition.

12. The vehicle as claimed in claim 11, wherein the container is partially transparent, and the image capturing module is a short-wave infrared (SWIR) camera.

13. The vehicle as claimed in claim 11, wherein the container comprises a lid which includes a transparent window, and the image capturing module tool takes images of the photomask via the transparent window.

14. The vehicle as claimed in claim 13, wherein the transparent window of the lid is aligned with an alignment mark formed on the photomask.

15. The vehicle as claimed in claim 11, wherein the image capturing module is positioned at a bottom of the main body with a lens facing upward.

16. A method, comprising:
transferring a container along with a photomask received therein from a first tool to a second tool using a vehicle;
producing an image of the photomask while the photomask is positioned in the container;
determining whether an orientation of the photomask in the container meets a preset condition;
when the orientation of the photomask does not meet the preset condition, suspending the transfer of the container from the first tool to the second tool and delivering the container along with the photomask to a flipping machine; and
performing a photomask flapping process on the photomask when the orientation of the photomask does not meet the preset condition.

17. The method as claimed in claim 16, wherein when the orientation of the photomask meets the preset condition, the transfer of the container to the second tool continues and a second fabrication process is performed on the photomask by using the second tool, wherein the second fabrication process is different from a first fabrication process that is performed on the photomask in the first tool.

18. The method as claimed in claim 17, wherein the second fabrication process is performed for transferring a pattern to a layer formed on the photomask.

19. The method as claimed in claim 16, wherein the image of the photomask is produced while the transfer of the container.

20. The method as claimed in claim 16, wherein the container is partially transparent, and the image capturing module is a short-wave infrared (SWIR) camera.
